(19) United States
(12) Patent Application Publication
(10) Pub. No.: US 2026/0279459 A1
(43) Pub. Date: Sep. 17, 2026

(54) INTERFACE CHIP, SEMICONDUCTOR MEMORY DEVICE, AND MEMORY SYSTEM

(71) Applicant: Kioxia Corporation, Tokyo (JP)

(72) Inventors: Shun NAGAI, Sagamihara (JP); Takehisa KUROSAWA, Yokohama (JP); Katsuki MATSUDERA, Kawasaki (JP)

(73) Assignee: Kioxia Corporation, Tokyo (JP)

(21) Appl. No.: 19/329,736

(22) Filed: Sep. 16, 2025

(30) Foreign Application Priority Data
Mar. 14, 2025 (JP) 2025-041184

(51) Int. Cl. G11C 16/26; G11C 16/08; G11C 16/32

(52) U.S. Cl. CPC G11C 16/26; G11C 16/08; G11C 16/32

(57) ABSTRACT

An interface chip includes a first signal line, a second signal line, and a third signal line that receive a signal from a memory controller, a plurality of fourth signal lines that each transmits and receives a signal to and from the memory controller, a plurality of fifth signal lines that each transmits and receives a signal to and from a first memory chip including a plurality of memory cells, a storage, and a controller transmits, in a case where a first signal transmitted from the memory controller via the third signal line is at a first logic level, after a first command for the read operation transmitted from the memory controller is received via the first signal line and the second signal line, a second command for the read operation, the second command corresponding to the first command, to the first memory chip via the fifth signal lines.

### CROSS REFERENCE TO RELATED APPLICATIONS

This application is based upon and claims the benefit of priority from the prior Japanese Patent Application No. 2025-041184, filed on Mar. 14, 2025, the entire contents of which are incorporated herein by reference.

### FIELD

An embodiment of the present invention relates to an interface chip, a semiconductor memory device, and a memory system.

### BACKGROUND

When a controller has issued a data output command to a memory chip such as a flash memory, the memory chip prepares (presets) to output data that corresponds to a column address described in the data output command. During a preset period, the controller fails to access the memory chip, and therefore the preset period is an obstacle to increase the speed of accessing the memory chip.

### BRIEF DESCRIPTION OF THE DRAWINGS

FIG. 1 is a block diagram of a memory system according to the present embodiment;

FIG. 2 is a block diagram of a semiconductor memory device included in the memory system according to the present embodiment;

FIG. 3 is a block diagram of a NAND chip CP0 in the semiconductor memory device included in the memory system according to the present embodiment;

FIG. 4 is a block diagram illustrating a configuration of a NAND chip included in the memory system according to the present embodiment, focusing on a plane;

FIG. 5 is a circuit diagram of a memory cell array in a plane included in the memory system according to the present embodiment;

FIG. 6 is a diagram explaining a method for reading data by using a normal protocol;

FIG. 7A is a diagram illustrating a signal CLE or ALE that is input to a CLE terminal or an ALE terminal, a signal WE that is input to a WE terminal, and a command/address or data on a DQ bus at the time of selecting the normal protocol;

FIG. 7B is a diagram illustrating a signal CA_CLK, a signal CA[1], and a signal CA[0] that are input to the WE terminal, the CLE terminal, and the ALE terminal at the time of selecting an SCA protocol;

FIG. 8A is a diagram illustrating a read operation period and a data transmission period in a case where two NAND chips are connected to one channel;

FIG. 8B is a diagram illustrating a read operation period and a data transmission period in a case where eight NAND chips are connected to one channel;

FIG. 9 is a block diagram illustrating an internal configuration of an I/F chip according to the present embodiment;

FIG. 10A is a schematic timing diagram of the memory system according to the present embodiment;

FIG. 10B is a timing diagram of a memory system according to a comparative example;

FIG. 11 is a diagram illustrating a connection relationship among a memory controller, an I/F chip, and two NAND chips according to a first specific example;

FIG. 12 is a timing diagram of the first specific example;

FIG. 13 is a diagram illustrating a connection relationship among a memory controller and two NAND chips according to a comparative example;

FIG. 14 is a timing diagram of the comparative example;

FIG. 15 is a diagram illustrating a connection relationship among a memory controller, an I/F chip, and two NAND chips according to a second specific example;

FIG. 16 is a timing diagram of the second specific example;

FIG. 17 is a timing diagram of a third specific example;

FIG. 18 is a diagram illustrating a connection relationship among a memory controller, an I/F chip, and two NAND chips according to a fourth specific example;

FIG. 19 is a timing diagram of the fourth specific example;

FIG. 20A is a diagram illustrating a first mounting example of the semiconductor memory device according to the present embodiment;

FIG. 20B is a diagram illustrating a second mounting example of the semiconductor memory device according to the present embodiment; and

FIG. 20C is a diagram illustrating a third mounting example of the semiconductor memory device according to the present embodiment.

### DETAILED DESCRIPTION

In general, according to the embodiment, an interface chip includes a first signal line, a second signal line, and a third signal line, each of the first signal line, the second signal line, and the third signal line being configured to receive a signal from a memory controller, a plurality of fourth signal lines, each of the plurality of fourth signal lines being configured to transmit and receive a signal to and from the memory controller, a plurality of fifth signal lines, each of the plurality of fifth signal lines being configured to transmit and receive a signal to and from a first memory chip including a plurality of memory cells, a storage, and a controller configured to, in a case where a first signal transmitted from the memory controller via the third signal line is at a first logic level. The controller transmits, after receiving a first command for the read operation transmitted from the memory controller via the first signal line and the second signal line, a second command for the read operation, the second command corresponding to the first command, to the first memory chip via a plurality of fifth signal lines, transmits a fourth command for data output to the first memory chip via the plurality of fifth signal lines, after the read operation performed by the first memory chip and before receiving a third command for the data output from the memory controller via the first signal line and the second signal line, receives, via the plurality of fifth signal lines, first data being output from the first memory chip in response to the fourth command transmitted to the first memory chip, causes the storage to hold the received first data, and transmits the held first data to the memory controller via a plurality of fourth signal lines, after receiving the third command.

Hereinafter, an embodiment of an interface chip, a semiconductor memory device, and a memory system will be described with reference to the drawings. Principal components of the interface chip, the semiconductor memory device, and the memory system will be mainly described below, but the interface chip, the semiconductor memory device, and the memory system can include components or functions that are not illustrated or described. The description below does not exclude the components or functions that are not illustrated or described.

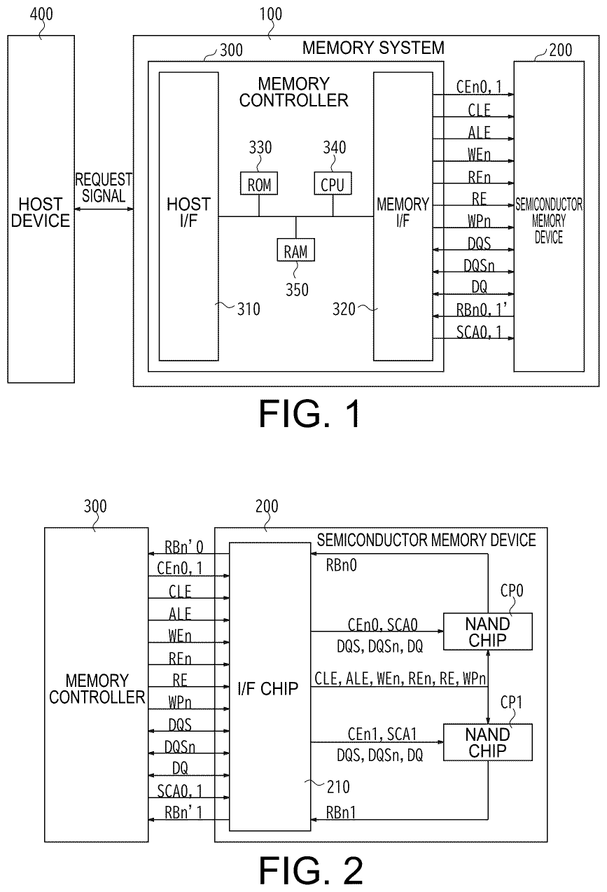

FIG. 1 is a block diagram of a memory system according to the present embodiment.

A memory system 100 includes a semiconductor memory device 200 and a memory controller 300. The memory system 100 is controlled by a host device (hereinafter simply referred to as a “host”) 400. The memory system 100 performs processing based on a request signal that has been received from the host 400. The memory system 100 is, for example, a solid state drive (SSD), a universal serial bus (USB) memory, a multi-media card (MMC), or an SD™ card. The host 400 is, for example, a digital camera or a personal computer.

As described later, the semiconductor memory device 200 includes, for example, an interface chip (hereinafter, an I/F chip) and a NAND chip, and stores data in a nonvolatile manner. A plurality of NAND chips may be provided in the semiconductor memory device 200.

The memory controller 300 receives a request signal from the host 400 via a host bus. The type of the host bus and the request signal transmitted via the host bus depend on an application applied to the memory system 100. In a case where the memory system 100 is an SSD, for example, an interface of the standard of serial attached SCSI (SAS), serial ATA (SATA), programmable communications interface express (PCIe™), or universal flash storage (UFS) is used as the host bus. In a case where the memory system 100 is a USB memory, the USB is used as the host bus. In a case where the memory system 100 is an MMC, an interface of the eMMC standard is used as the host bus. In a case where the memory system 100 is an SD™ card, an interface of the SD™ standard is used as the host bus. Herein, the memory controller 300 is referred to as a controller in some cases.

The memory controller 300 controls the semiconductor memory device 200 on the basis of the request signal that has been received from the host 400. Therefore, the memory controller 300 is connected to the semiconductor memory device 200 via a NAND bus. The NAND bus transmits and receives a signal according to a NAND interface. Specific examples of this signal are chip enable signals CEn0 and CEn1, a command latch enable signal CLE, an address latch enable signal ALE, a write enable signal WEn, read enable signals REn and RE, a write protect signal WPn, data strobe signals DQS and DQSn, an input/output signal DQ, a ready/busy signal RBn, and a separate command address (SCA) switching signal SCA.

The signals CEn0 and CEn1 are signals for enabling the NAND chip in the semiconductor memory device 200, and are asserted at a low (“L”) level, for example. Note that “assert” means that a signal (or a logic) is in a valid (active) state. The signal CLE is a signal indicating that the signal DQ is a command, and is asserted at a high (“H”) level, for example. The signal ALE is a signal indicating that the signal DQ is an address, and is asserted at the “H” level, for example. The signal WEn is a signal for taking a received signal into the semiconductor memory device 200, and is asserted at the low level, for example. Each time WEn is toggled, the semiconductor memory device 200 captures the signal DQ. The signals REn and RE are signals for the memory controller 300 to read data from the semiconductor memory device 200. The signal REn is an inverted signal of the signal RE. Each time the signals REn and RE are toggled, the semiconductor memory device 200 outputs the signal DQ to the memory controller 300. The signal WPn is a signal for prohibiting writing to or erasing from the semiconductor memory device 200, and is asserted at the low level, for example. The signals CEn0, CEn1, CLE, ALE, WEn, REn, RE, and WPn are transmitted from the memory controller 300 to the semiconductor memory device 200.

The signals DQS and DQSn are used to control a timing of transmitting/receiving the signal DQ. The signal DQSn is an inverted signal of the signal DQS. For example, at the time of writing data, the signal DQS and the signal DQSn, together with the signal DQ reflecting write data, are transmitted from the memory controller 300 to the semiconductor memory device 200. The semiconductor memory device 200 can receive the write data by receiving the signal DQ in synchronization with the signal DQS and the signal DQSn. Furthermore, at the time of reading data, the signal DQS and the signal DQSn, together with read data DQ, are transmitted from the semiconductor memory device 200 to the memory controller 300. The signal DQS and the signal DQSn are generated on the basis of the signal REn described above. The memory controller 300 receives the read data DQ in synchronization with the signal DQS and the signal DQSn.

The input/output signal DQ is, for example, an 8-bit signal (hereinafter, in a case where eight signals DQ are distinguished from each other, the eight signals DQ are respectively described as signals DQ0 to DQ7, and in a case where the eight signals DQ are not distinguished from each other, the eight signals DQ are simply described as signals DQ). The input/output signal DQ is an entity of data transmitted and received between the semiconductor memory device 200 and the memory controller 300, and includes, for example, a command CMD, an address ADD, write data or read data DAT, and status information STS. Herein, a bus that transmits the input/output signal DQ is referred to as a DQ bus. A bus for transmitting a signal, such as the DQ bus, is also referred to as a signal line.

A signal RBn′ is a signal indicating whether the semiconductor memory device 200 is in a busy state or a ready state, and is set to the low level, for example, when the semiconductor memory device 200 is in the busy state. In a case where the signal RBn′ is in the ready state, the semiconductor memory device 200 can receive a command from the memory controller 300, and in a case where the signal RBn′ is in the busy state, the semiconductor memory device 200 fails to receive a command from the memory controller 300. The signal RBn′ is transmitted from the semiconductor memory device 200 to the memory controller 300.

The signal SCA is a signal that specifies whether to switch from the normal protocol to the SCA protocol. For example, the normal protocol is selected when the signal SCA is at the low level, and the SCA protocol is selected when the signal SCA is at the high level. The normal protocol and the SCA protocol differ in functions of the signals CLE, ALE, and WEn. At the time of selecting the normal protocol, the signal CLE is used as a signal indicating that the input/output signal DQ is a command, the signal ALE is used as a signal indicating that the input/output signal DQ is an address, and the signal WEn is used as a signal for capturing the signal DQ, for example, at a rising edge. At the time of selecting the SCA protocol, the signal CLE and the signal ALE are used to transmit a command or an address, and the signal WEn is used as a signal for capturing the signal CLE and the signal ALE, for example, at both a rising edge and a falling edge.

The memory controller 300 includes a host interface circuit (a host I/F) 310, a memory interface circuit (a memory I/F) 320, a read only memory (ROM) 330, a central processing unit (CPU) 340, and a random access memory (RAM) 350.

The host interface circuit 310 is connected to the host 400 via the host bus, and manages communication between the memory controller 300 and the host 400.

The memory interface circuit 320 is connected to the semiconductor memory device 200 via the NAND bus, and manages communication between the memory controller 300 and the semiconductor memory device 200.

The ROM 330 stores firmware (a program) for the memory controller 300 to execute various operations and some of the functions of the host interface circuit 310 and the memory interface circuit 320. The firmware is configured to enable the memory controller 300 to perform the operations described as respective embodiments.

The CPU 340 controls an operation of the entirety of the memory controller 300. For example, when the CPU 340 has received a request signal relating to reading, from the host 400, the CPU 340 causes the memory interface circuit 320 to issue a read command to the semiconductor memory device 200 on the basis of the request signal. When the CPU 340 has received a request signal relating to writing, from the host 400, the CPU 340 performs a similar operation.

The RAM 350 is used as a work area of the CPU 340. The RAM 350 is, for example, a semiconductor memory such as a DRAM or an SRAM. The RAM 350 stores, for example, the firmware described above. The firmware described above is loaded into the RAM 350 by the memory controller 300, for example, immediately after the memory system 100 has been powered on.

### Configuration of Semiconductor Memory Device 200

A configuration of the semiconductor memory device 200 will be described with reference to FIG. 2. FIG. 2 is a block diagram of the semiconductor memory device 200 that is included in the memory system 100 according to the present embodiment.

The semiconductor memory device 200 includes an I/F chip 210 and a plurality of NAND chips CP0 and CP1. Note that the number of the plurality of NAND chips CP0 and CP1 is arbitrary. The I/F chip 210 is connected to the memory controller 300 via the NAND bus, and manages communication between the memory controller 300 and the NAND chips CP0 and CP1. The NAND chips CP0 and CP1 are NAND flash memories. The NAND chips CP0 and CP1 are controlled by the memory controller 300. The I/F chip 210 may form a semiconductor device by itself.

FIG. 2 illustrates an example in which the memory controller 300 transmits the signal CEn0 or CEn1 that is different for each of the NAND chips, but the memory controller 300 may transmit a common signal CEn to the plurality of NAND chips. FIG. 2 illustrates an example in which the signal CEn0 is transmitted to the NAND chip CP0 and the signal CEn1 is transmitted to the NAND chip CP1. In a case where the common signal CEn is transmitted to the plurality of NAND chips, each of the NAND chips CP0 and CP1 is selected on the basis of the signal CEn and an address designating the NAND chip. The signal RBn includes signals RBn0 and RBn1 that correspond to the NAND chips CP0 and CP1, respectively. The signal SCA includes signals SCA0 and SCA1 that correspond to the NAND chips CP0 and CP1, respectively. Note that the number of signals RBn is a number that is the same as the number of NAND chips provided in the semiconductor memory device 200.

The I/F chip 210 receives, from the memory controller 300, the signals CEn0, CEn1, CLE, ALE, WEn, REn, RE, WPn, DQS, DQSn, and DQ. The I/F chip 210 transmits the received signals CLE, ALE, WEn, REn, RE, WPn, DQS, DQSn, and DQ to the NAND chips CP0 and CP1 via a data bus DB. The I/F chip 210 transmits the received signal CEn0 to the NAND chip CP0. The I/F chip 210 transmits the received signal CEn1 to the NAND chip CP1.

The I/F chip 210 receives the signals DQS, DQSn, and DQ from the NAND chips CP0 and CP1. The I/F chip 210 transmits the received signals DQS, DQSn, and DQ to the memory controller 300.

The NAND chip CP0 transmits the signal RBn0 to the I/F chip 210. The I/F chip 210 transmits, to the memory controller 300, a signal RBn′0 that corresponds to the NAND chip CP0. The NAND chip CP1 transmits the signal RBn1 to the I/F chip 210. The I/F chip 210 transmits, to the memory controller 300, a signal RBn′1 that corresponds to the NAND chip CP1.

Data is written to one selected from the NAND chips CP0 and CP1. In addition, data is read from one selected from the NAND chips CP0 and CP1.

### Configuration of NAND Chip CP0

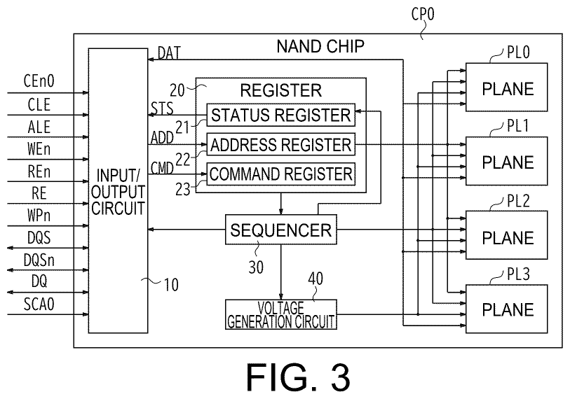

A configuration of the NAND chip CP0 will be described with reference to FIG. 3. FIG. 3 is a block diagram of the NAND chip CP0 in the semiconductor memory device 200 included in the memory system 100 according to the present embodiment. In FIG. 3, some of connections between blocks are rendered with arrow lines, but connection between blocks is not limited thereto. The NAND chip CP0 will be described below, and the NAND chip CP1 also has the same configuration.

The NAND chip CP0 includes an input/output circuit 10, a register 20, a sequencer 30, a voltage generation circuit 40, and planes PL0 to PL3.

The input/output circuit 10 receives the signals CEn0, SCA0, CLE, ALE, WEn, REn, RE, and WPn from the I/F chip 210. The input/output circuit 10 transmits and receives the signals DQS, DQSn, and DQ to and from the I/F chip 210. The input/output circuit 10 transmits the signal RBn0 to the I/F chip 210.

The register 20 includes a status register 21, an address register 22, and a command register 23. The status register 21 temporarily stores, for example, status information STS in operations to write, read, and erase data. The address register 22 temporarily stores the address ADD that has been received from the I/F chip 210 via the input/output circuit 10. The address ADD includes a row address RA and a column address CA. The command register 23 temporarily stores the command CMD that has been received from the I/F chip 210 via the input/output circuit 10.

The sequencer 30 controls an operation of the entirety of the NAND chip CP0. The sequencer 30 receives the command CMD from the command register 23. The sequencer 30 controls the input/output circuit 10, the status register 21, the voltage generation circuit 40, and the plane PL0 to the plane PL3 (PL0 to PL3) on the basis of the received command CMD, and executes write, read, and erase operations, and the like.

The voltage generation circuit 40 receives a power supply voltage from the outside of the NAND chip CP0, and generates various voltages from the power supply voltage under the control of the sequencer 30. The voltage generation circuit 40 applies the generated voltage to the plane PL0 to the plane PL3 (PL0 to PL3).

The plane PL0 to the plane PL3 (PL0 to PL3) are independently controlled by the sequencer 30. The plane PL0 to the plane PL3 (PL0 to PL3) are units that write data to the memory cell transistor described later and read data from the memory cell transistor described later. When writing data, the plane PL0 to the plane PL3 (PL0 to PL3) receive write data DAT from the memory controller 300 via the input/output circuit 10. In addition, when reading data, the plane PL0 to the plane PL3 (PL0 to PL3) transmit the data DAT that has been read, to the I/F chip 210 via the input/output circuit 10.

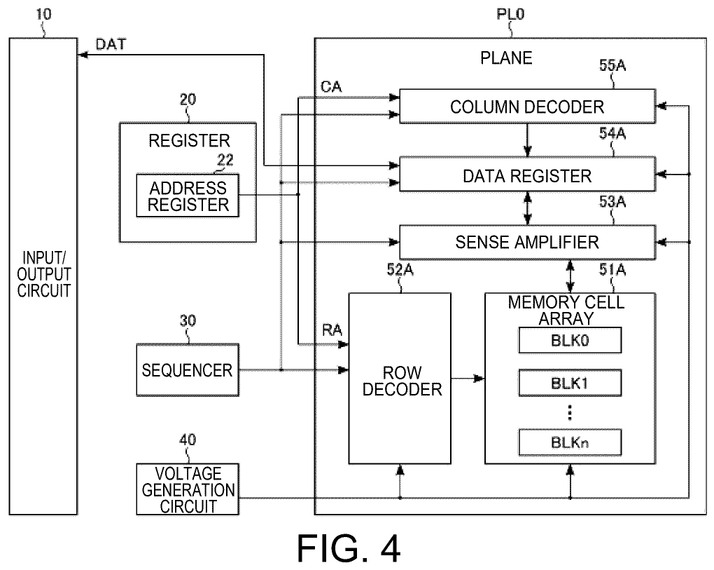

A configuration of the plane PL0 will be described with reference to FIG. 4. FIG. 4 is a block diagram illustrating a configuration of the NAND chip CP0 included in the memory system 100 according to the present embodiment, focusing on the plane PL0. The plane PL0 will be described below, and the plane PL1, the plane PL2, and the plane PL3 also have the same configuration. Note that, in FIG. 4, the status register 21, the command register 23, and the plane PL1 to the plane PL3 (PL1 to PL3) are omitted.

The plane PL0 includes a memory cell array 51A, a row decoder 52A, a sense amplifier 53A, a data register 54A, and a column decoder 55A.

The memory cell array 51A includes a plurality of blocks BLK (BLK0 to BLKn, where n is a natural number of 1 or more) that each includes nonvolatile memory cell transistors that are associated with rows and columns. Note that the number of blocks BLK in the memory cell array 51A is arbitrary. Details of the memory cell array 51A will be described later. A voltage is applied to the memory cell array 51A from the voltage generation circuit 40.

The row decoder 52A is controlled by the sequencer 30. The row decoder 52A receives the row address RA from the address register 22. The row decoder 52A decodes the received row address RA, and applies the voltage supplied from the voltage generation circuit 40, to a selected memory cell transistor on the basis of a decoding result.

The sense amplifier 53A is controlled by the sequencer 30. A voltage is applied to the sense amplifier 53A from the voltage generation circuit 40. When reading data, the sense amplifier 53A senses the data DAT that has been read from the memory cell array 51A. The sense amplifier 53A transmits the data DAT that has been read, to the data register 54A. When writing data, the sense amplifier 53A transmits write data DAT to the memory cell array 51A.

The data register 54A is controlled by the sequencer 30. A voltage is applied to the data register 54A from the voltage generation circuit 40. The data register 54A includes a plurality of latch circuits (not illustrated). The latch circuit stores write data and read data DAT. For example, when writing data, the data register 54A temporarily stores the write data DAT that has been received from the input/output circuit 10, and transmits the write data DAT to the sense amplifier 53A. When reading data, the data register 54A temporarily stores the read data DAT that has been received from the sense amplifier 53A, and transmits the read data DAT to the input/output circuit 10.

The column decoder 55A is controlled by the sequencer 30. A voltage is applied to the column decoder 55A from the voltage generation circuit 40. The column decoder 55A receives the column address CA from the address register 22. At the time of, for example, write, read, and erase operations, the column decoder 55A decodes the column address CA, and selects a latch circuit in the data register 54A according to a decoding result.

### Circuit Configuration of Memory Cell Array 51A

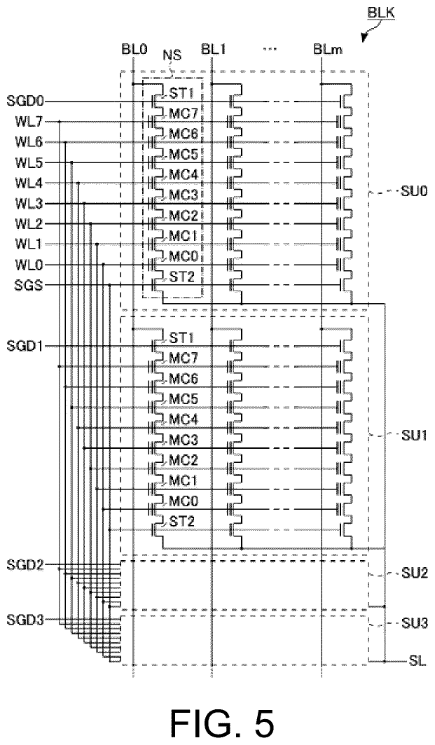

A circuit configuration of the memory cell array 51A will be described with reference to FIG. 5. FIG. 5 is a circuit diagram of the memory cell array 51A in the plane PL0 included in the memory system 100 according to the present embodiment.

FIG. 5 illustrates an example of the circuit configuration of the memory cell array 51A by extracting one block BLK of the plurality of blocks BLK included in the memory cell array 51A. All of the other blocks BLK have the configuration illustrated in FIG. 5.

The block BLK includes, for example, four string units SU0 to SU3. Note that the number of string units SU in the block BLK is arbitrary. Each of the string units SU includes a plurality of NAND strings NS. The plurality of NAND strings NS is associated with bit lines BL0 to BLm (m is a natural number of 1 or more), respectively. Each of the NAND strings NS includes, for example, memory cell transistors MC0 to MC7 and selection transistors ST1 and ST2. The memory cell transistor MC includes a control gate and a charge storage layer, and stores data in a nonvolatile manner. Each of the selection transistors ST1 and ST2 is used to select a string unit SU during various operations.

In each of the NAND strings NS, the memory cell transistors MC0 to MC7 are connected in series. In an identical block BLK, the control gates of the memory cell transistors MC0 to MC7 are commonly connected to word lines WL0 to WL7, respectively.

In each of the NAND strings NS, the drain of the selection transistor ST1 is connected to an associated bit line BL, and the source of the selection transistor ST1 is connected to one end of the memory cell transistors MC0 to MC7 that are connected in series. In an identical block BLK, the gates of the selection transistors ST1 in the string units SU0 to SU3 are commonly connected to selection gate lines SGD0 to SGD3, respectively.

In each of the NAND strings NS, the drain of the selection transistor ST2 is connected to another end of the memory cell transistors MC0 to MC7 that are connected in series. In an identical block BLK, the sources of the selection transistors ST2 are connected to a source line SL, and the gates of the selection transistors ST2 are commonly connected to a selection gate line SGS.

In the circuit configuration described above of the memory cell array 51A, the bit line BL is shared, for example, by a plurality of corresponding NAND strings NS in each of the blocks BLK. The source line SL is shared, for example, by the plurality of blocks BLK.

### (Reading Data by Using Normal Protocol)

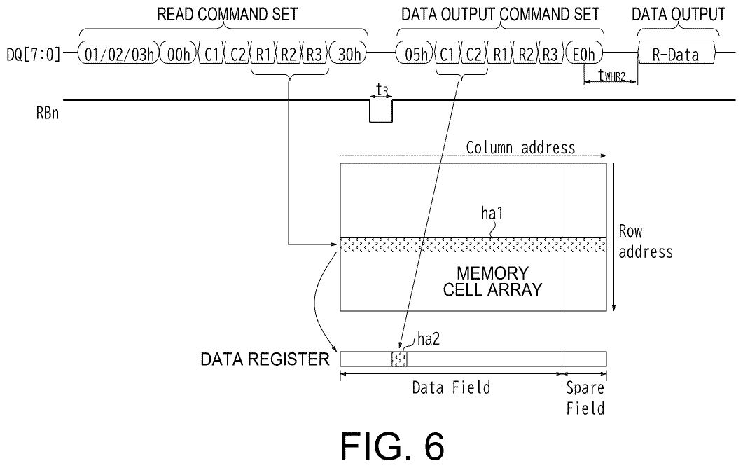

In a case where data stored in the NAND chip CP is read by using the normal protocol, the memory controller 300 transmits a command/address and data via an 8-bit DQ bus. FIG. 6 is a diagram explaining a method for reading data by using the normal protocol. The memory controller 300 first issues a read command set via the DQ bus. The read command set includes information relating to a specified row address. Herein, the read command set is abbreviated as a read command in some cases.

When the NAND chip CP has received the read command set issued by the memory controller 300, the NAND chip CP performs an operation to read a row address designated by the read command set. FIG. 6 illustrates an example in which an operation to read a specified row address (a hatched area ha1) of a memory cell array in a specified plane is performed by using the read command set issued by the memory controller 300. The NAND chip CP does not occupy the DQ bus during a period (hereinafter, a read operation period) tR required for the NAND chip CP to perform a read operation, and therefore the memory controller 300 can issue a read command to another NAND chip CP during the read operation period tR.

When the NAND chip CP has terminated the read operation, the memory controller 300 issues a data output command set. The data output command set includes information relating to a specified column address in a specified row address. Herein, the data output command set is abbreviated as a data output command in some cases.

When the NAND chip CP has received the data output command set that has been issued by the memory controller 300 via the DQ bus, the NAND chip CP prepares to output data in a column address (a hatched area ha2) designated by the data output command set, and when the NAND chip CP is ready to output the data, the NAND chip CP outputs the data via the DQ bus.

A data output preparation period tWHR2 is a period for preparing to output data via the DQ bus, and the memory controller 300 fails to issue a command during this period tWHR2.

As described above, in a case where the memory controller 300 performs data reading by using the normal protocol, a command fails to be issued during the data output preparation period tWHR2, and this causes a problem in which latency fails to be improved.

### SCA Protocol

In the normal protocol, the memory controller 300 and the I/F chip 210 transmit a command/address and data via an 8-bit DQ bus in a time division switching manner. Therefore, during the transmission of the command/address, the DQ bus is occupied, and data fails to be transmitted, and the efficiency of transmitting data deteriorates. In view of such circumstances, the SCA protocol, which is the specifications for transmitting a command/address and data via separate buses without changing a terminal configuration of an existing NAND chip CP, has been standardized by the Joint Electron Device Engineering Councils (JEDEC).

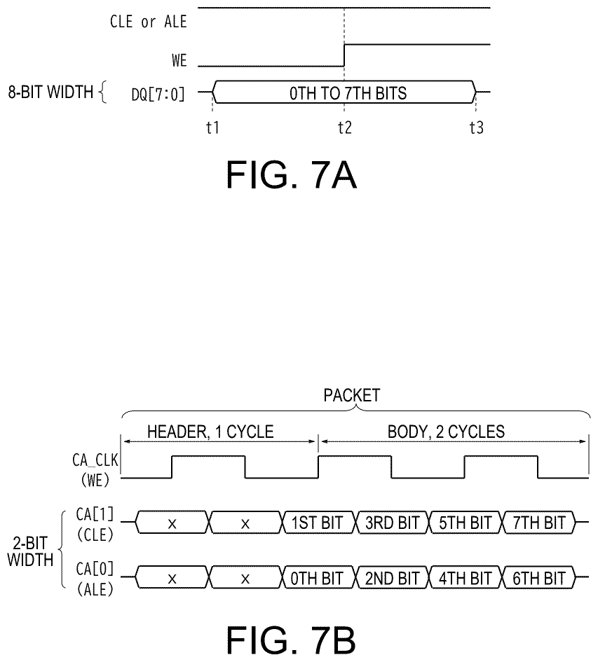

The normal protocol and the SCA protocol differ in functions of respective signals that are input to a CLE terminal, an ALE terminal, and a WE terminal of the NAND chip CP. FIG. 7A is a diagram illustrating a signal CLE or ALE that is input to the CLE terminal or the ALE terminal, a signal WE that is input to the WE terminal, and a command/address or data on the DQ bus at the time of selecting the normal protocol. As illustrated, the signal WE changes from the low level to the high level at time t2 in the middle of a period (time t1 to time t3) during which the DQ bus transmits an 8-bit command/address or data. The signal logic of the signal CLE or ALE does not change during a period from time t1 to time t3. The DQ bus is latched by the signal WE at time t2 when the signal WE changes from the low level to the high level. On the DQ bus, an 8-bit command/address is transmitted in some cases, and 8-bit data is transmitted in other cases.

FIG. 7B is a diagram illustrating a signal CA_CLK, a signal CA[1], and a signal CA[0] that are input to the WE terminal, the CLE terminal, and the ALE terminal at the time of selecting the SCA protocol. A command/address that would be transmitted by using the 8-bit DQ bus in the normal protocol is transmitted by using two bits of CA[0:1], by using the CLE terminal and the ALE terminal, in the SCA protocol. Therefore, in the SCA protocol, CA[0:1] is formed into a packet format. The packet CA[0:1] includes a 4-bit header and an 8-bit body. The header includes 4-bit information that distinguishes a command and an address. The body includes 8-bit information that indicates a command or an address.

In the normal protocol, an 8-bit command/address can be transmitted in one cycle of the signal WE, by using a DQ bus having an 8-bit width. In contrast, in the SCA protocol, a command/address is transmitted in the packet CA[0:1] having a 2-bit width, and therefore four cycles are required to transmit the 8-bit command/address, and two cycles are required to transmit the header, so that six cycles in total are required. Therefore, CA[0:1] is captured not only at a rising edge of the signal WE but also at a falling edge.

The SCA protocol is intended to enhance the efficiency of the DQ bus to the maximum, and the efficiency varies depending on an occupancy rate of the DQ bus. The occupancy rate of the DQ bus depends on a time period tR during which data is read from the NAND chip CP and a period tDout during which the read data is transmitted.

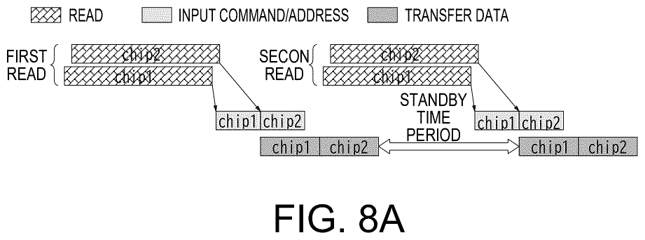

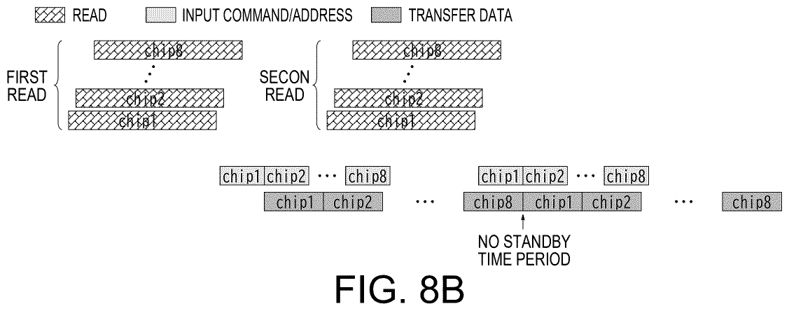

FIG. 8A is a diagram illustrating a read operation period tR and a data transmission period Dout in a case where two NAND chips CP are connected to one channel, and FIG. 8B is a diagram illustrating a read operation period tR and a data transmission period Dout in a case where eight NAND chips CP are connected to one channel. FIGS. 8A and 8B illustrate a read operation period tR of the NAND chip CP, an input period of a data output command, and a transmission period tDout of read data.

A read operation period required to read data from the NAND chip CP is longer than a data transmission period, and therefore if the number of NAND chips CP per channel is small, as illustrated in FIG. 8A, a standby time period of reading increases. If the standby time period is long, the DQ bus fails to be efficiently used, and this reduces an advantage of adopting the SCA protocol.

On the other hand, as illustrated in FIG. 8B, in a case where the number of NAND chips CP per channel is large, reading can be performed in parallel on the respective NAND chips CP, and therefore the standby time period of reading can be reduced, and the occupancy rate of the DQ bus can be improved. Therefore, the SCA protocol is effective in a case where the number of NAND chips CP per channel is large.

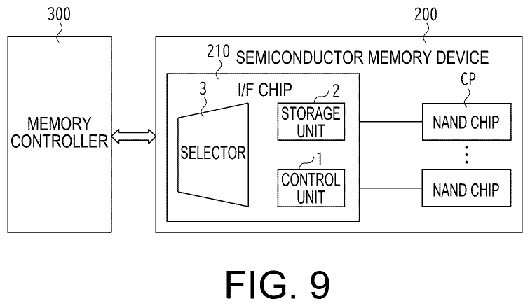

FIG. 9 is a block diagram illustrating an internal configuration of the I/F chip 210 according to the present embodiment. FIG. 9 illustrates an example in which the I/F chip 210 and the plurality of NAND chips CP are housed in an identical package member to form the semiconductor memory device 200.

The I/F chip 210 according to the present embodiment includes a control unit 1, as illustrated in FIG. 9. The control unit 1 controls the plurality of NAND chips CP. The control unit 1 transmits a command to each of the NAND chips CP at a timing that is independent of a timing at which a command issued by the memory controller 300 is input. The independent timing means that the I/F chip 210 can transmit, to a NAND chip CP, a command other than the command issued by the memory controller 300. An existing I/F chip 210 has a function of relaying communication between the memory controller 300 and the NAND chip CP, and transmits, to the NAND chip CP, a command issued by the memory controller 300 as it is. On the other hand, the I/F chip 210 according to the present embodiment can transmit, to the NAND chip CP, a command before being issued by the memory controller 300. As described above, the I/F chip 210 according to the present embodiment can not only transmit, to the NAND chip CP, a command issued by the memory controller 300, but can also transmit, to the NAND chip CP, a command that has not yet been issued by the memory controller 300. The control unit 1 is also referred to as a controller. Components in the control unit 1 are implemented by, for example, at least one of a register, a memory, an adder, a multiplier, a selector, and other arithmetic units. The register is implemented by, for example, a sequential circuit such as a flip-flop. The memory is implemented by, for example, a storage element such as an SRAM or a DRAM. The adder, the multiplier, the selector, and other arithmetic units are implemented by, for example, a combinational logic circuit. Components of elements other than the control unit 1 of the I/F chip 210 are also implemented by, for example, at least one of a register, a memory, an adder, a multiplier, a selector, and other arithmetic units.

In a more specific example, the control unit 1 transmits a command (for example, a data output command) to the NAND chip CP before the command is issued from the memory controller 300, and temporarily holds data that has been output from the NAND chip CP in response to the command that has been transmitted to the NAND chip CP, and when the command has been issued from the memory controller 300 after the control unit 1 has held the data, the control unit 1 transmits the held data to the memory controller 300. As a result, the I/F chip 210 can read ahead data stored in the NAND chip CP. Thereafter, when the memory controller 300 has issued a command, the read-ahead data can be quickly returned to the memory controller 300, and the latency can be reduced.

For example, regardless of whether the memory controller 300 adopts the separate command address (SCA) protocol, the control unit 1 transmits a command, an address, and data to and from the NAND chip CP via an identical bus. Alternatively, in a case where the memory controller 300 adopts the separate command address (SCA) protocol, the control unit 1 may transmit a command and an address to and from the NAND chip CP via a first bus, and may transmit data via a second bus that is different from the first bus.

In a more specific example, when the memory controller 300 has issued a read command, the control unit 1 transmits the read command to the NAND chip CP. After the NAND chip CP has performed a read operation in response to the read command and before the memory controller 300 issues a data output command, the control unit 1 transmits a data output command to the NAND chip CP.

The control unit 1 may transmit the data output command to the NAND chip CP, after the maximum allowable time period defined by the specifications has passed after the control unit 1 has transmitted the read command to the NAND chip CP and before the NAND chip CP terminates the read operation.

Alternatively, after the control unit 1 has transmitted the read command to the NAND chip CP, when the logic of a predetermined signal (for example, the ready/busy signal RBn) that has been transmitted from the NAND chip CP and indicates an operation state has changed, the control unit 1 may transmit the data output command to the NAND chip CP.

In a case where the memory controller 300 adopts the SCA protocol and continuously issues read commands for the plurality of NAND chips CP, the control unit 1 may perform, for each of the plurality of NAND chips CP, transmitting the read command and the data output command to a corresponding NAND chip CP and receiving data that has been output from the corresponding NAND chip CP at different timings, by using one bus.

In a case where the memory controller 300 adopts the SCA protocol and continuously issues read commands for the plurality of NAND chips CP, the control unit 1 may perform, for each of the plurality of NAND chips CP, receiving data that has been output from a corresponding NAND chip CP and transmitting the read command to the corresponding NAND chip CP in parallel, by using a first bus through which a command and an address are transmitted and a second bus through which data is transmitted.

In a case where the memory controller 300 has continuously issued read commands for the plurality of NAND chips CP, the control unit 1 may adjust, for each of the plurality of NAND chips CP, a timing of transmitting the read command or the data output command.

The I/F chip 210 according to the present embodiment may include a storage unit 2. The storage unit 2 temporarily holds data that has been output by a NAND chip CP that corresponds to a command (for example, the data output command) that has been transmitted to the NAND chip CP. The storage unit 2 is, for example, a cache memory including a static random access memory (SRAM) that is capable of performing reading and writing at high speed. When the memory controller 300 has issued the data output command after the storage unit 2 has held data, the control unit 1 performs control to quickly transmit the data held by the storage unit 2 to the memory controller 300.

In a case where the memory controller 300 has continuously issued read commands for the plurality of NAND chips CP, the control unit 1 continuously transmits the read commands to the plurality of NAND chips CP to cause the plurality of NAND chips CP to perform the read operation in parallel. When the plurality of NAND chips CP has terminated the read operation, the control unit 1 may continuously transmit data output commands for the plurality of NAND chips CP before the memory controller 300 issues the data output commands for the plurality of NAND chips CP, and may temporarily hold, in the storage unit 2, plural pieces of data that have been output in parallel by the plurality of NAND chips CP.

The I/F chip 210 according to the present embodiment may include a selector 3. The selector 3 selects any one of the plural pieces of data that have been output from the plurality of NAND chips CP and have been held in the storage unit 2, on the basis of the data output command that has been issued by the memory controller 300, and transmits the selected data to the memory controller 300.

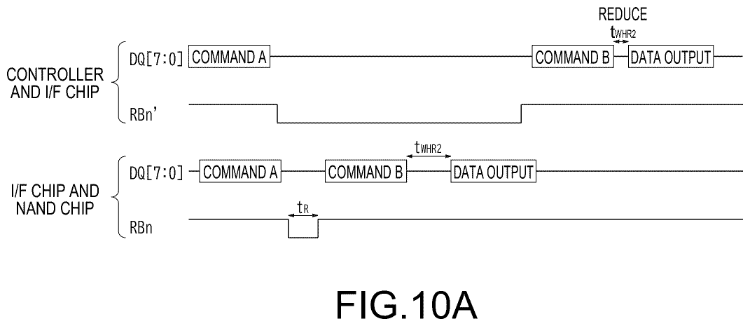

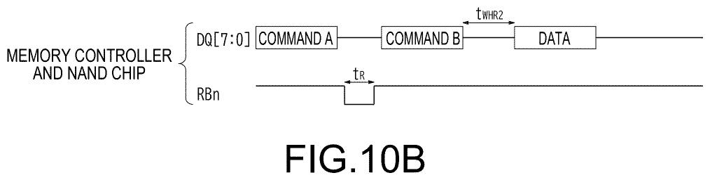

FIG. 10A is a schematic timing diagram of the memory system 100 according to the present embodiment. FIG. 10A illustrates a timing at which the memory controller 300 transmits a command to the I/F chip 210, and a timing at which the I/F chip 210 transmits a command to the NAND chip CP. A command A is, for example, a read command, and a command B is, for example, a data output command.

FIG. 10A illustrates timings in a case where the memory controller 300 adopts the normal protocol. As described above, in the normal protocol, the memory controller 300 transmits and receives a command/address and data to and from the I/F chip 210 via the DQ bus. In addition, the I/F chip 210 transmits and receives a command/address and data to and from the plurality of NAND chips CP via the DQ bus.

When the I/F chip 210 has received the command A from the memory controller 300, the I/F chip 210 transmits the command A to the NAND chip CP. When the NAND chip CP has received the command A from the I/F chip 210, the NAND chip CP performs a read operation according to the command A. The NAND chip CP sets the ready/busy signal RBn to the low level during the read operation period tR. The ready/busy signal RBn is transmitted from the NAND chip CP to the I/F chip 210. The NAND chip CP causes the ready/busy signal RBn to change from the high level to the low level during the read operation period tR.

When the ready/busy signal RBn has changed from the low level to the high level, the I/F chip 210 transmits the command B to the NAND chip CP before the memory controller 300 issues the command B. When the NAND chip CP has received the command B, the NAND chip CP performs data output preparation according to the command B. When the data output preparation period tWHR2 has finished, the NAND chip CP outputs data via the DQ bus. The I/F chip 210 temporarily holds this data in the storage unit 2.

The I/F chip 210 generates a ready/busy signal RBn′ addressed to the memory controller 300 on the basis of the ready/busy signal RBn from the NAND chip CP. The ready/busy signal RBn′ addressed to the memory controller 300 is a signal that changes from the high level to the low level when the I/F chip 210 has received the command A from the memory controller 300, and changes from the low level to the high level when the storage unit 2 has finished holding the data from the NAND chip CP.

After the memory controller 300 has issued the command A, when the ready/busy signal RBn′ from the I/F chip 210 has made a transition from the low level to the high level, the memory controller 300 issues the command B. When the I/F chip 210 has received the command B from the memory controller 300, the I/F chip 210 transmits the data held in the storage unit 2 to the memory controller 300. As a result, the memory controller 300 can quickly receive data that corresponds to the command B.

In a case where the memory controller 300 according to the present embodiment continuously transmits the command A (the read command) for two NAND chips CP, the I/F chip 210 can transmit the command A to one NAND chip CP while another NAND chip CP is performing the read operation. Therefore, a processing delay due to the read operation period tR does not occur. In addition, before the memory controller 300 issues the command B, the I/F chip 210 transmits the command B to each of the NAND chips CP, reads ahead the data of each of the NAND chips CP, and holds the pieces of data in the storage unit 2. As a result, when the memory controller 300 has subsequently issued the command B, data held in the storage unit 2 can be quickly transmitted to the memory controller 300. Therefore, the data output preparation period tWHR2 of the NAND chip CP does not cause a decrease in latency.

FIG. 10B is a timing diagram of a memory system according to a comparative example. The memory system according to the comparative example does not include the I/F chip 210, and a memory controller directly transmits a command to the NAND chip CP. When the memory controller has issued the command A and the NAND chip CP has received the command A, the NAND chip CP starts the read operation, and sets the ready/busy signal RBn to the low level until the read operation terminates. When the ready/busy signal RBn has made a transition from the low level to the high level, the memory controller issues the command B. When the NAND chip CP has received the command B, the NAND chip CP starts data output preparation. When the data output preparation has terminated, the NAND chip CP outputs data via the DQ bus.

The memory controller according to the comparative example fails to transmit a command via the DQ bus during the data output preparation period tWHR2, and therefore the latency increases, and the reading speed of the NAND chip CP fails to be increased.

Hereinafter, detailed timings in a case where the memory controller 300 according to the present embodiment issues a read command and a data output command for two NAND chips CPA and CPC, and reads corresponding pieces of data from the NAND chips CPA and CPC will be described. In the present embodiment, there is no single method for reading data from the two NAND chips CPA and CPC, and several methods can be applied. Hereinafter, plural representative methods for reading data from the two NAND chips CPA and CPC will be sequentially described as first to fourth specific examples. Hereinafter, a read command and a data output command that are addressed to the NAND chip CPA are referred to as a read command A and a data output command A, respectively, and a read command and a data output command that are addressed to the NAND chip CPC are referred to as a read command C and a data output command C, respectively, in some cases.

### First Specific Example

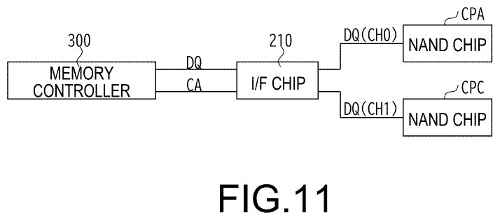

FIG. 11 is a diagram illustrating a connection relationship among the memory controller 300, the I/F chip 210, and the two NAND chips CPA and CPC according to the first specific example. The two NAND chips CPA and CPC configure, for example, a channel 0(CH0 ) and a channel 1 (CH1) in an identical plane. The memory controller 300 according to the first specific example adopts the SCA protocol. As described above, in the SCA protocol, the memory controller 300 transmits data and a command/address to and from the I/F chip 210, by using a DQ bus dedicated to data and a CA bus dedicated to a command/address. In addition, a command/address and data are transmitted between the I/F chip 210 and each of the NAND chips CP via a DQ bus.

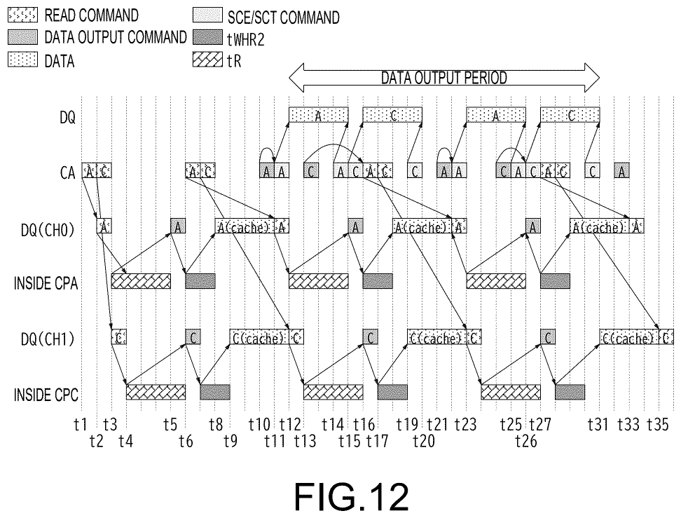

FIG. 12 is a timing diagram of the first specific example. FIG. 12 illustrates timings of the DQ bus and the CA bus between the memory controller 300 and the I/F chip 210, a DQ (CH0) bus between the I/F chip 210 and the NAND chip CPA, an internal operation of the NAND chip CPA, a DQ (CH1) bus between the I/F chip 210 and the NAND chip CPC, and an internal operation of the NAND chip CPC.

Hereinafter, an example in which the memory controller 300 issues a read command and a data output command for the two NAND chips CPA and CPC will be described.

First, at time t1, the memory controller 300 transmits the read command A for the NAND chip CPA via the DQ bus. Upon receiving the read command A, at time t2, the I/F chip 210 transmits the read command A to the NAND chip CPA via the DQ (CH0) bus.

At time t2, the memory controller 300 transmits the read command C for the NAND chip CPC via the DQ bus. Upon receiving the read command C, at time t3, the I/F chip 210 transmits the read command C to the NAND chip CPC via the DQ (CH1) bus.

Upon receiving the read command A, at time t3, the NAND chip CPA starts the read operation. Time t3 to time t5 is the read operation period tR. During the read operation period tR, the NAND chip CPA reads data of one page specified by a row address included in the read command A. The ready/busy signal RBn transmitted from the NAND chip CPA to the I/F chip 210 has the low level during the read operation period tR, and changes to the high level when the read operation period tR has finished.

Then, upon receiving the read command C, at time t4, the NAND chip CPC starts the read operation. Time t4 to time t6 is the read operation period tR. During the read operation period, the NAND chip CPC reads data of one page indicated by a row address included in the read command C.

When the read operation period of the NAND chip CPA has finished, the I/F chip 210 transmits a data output command to the NAND chip CPA at time t5 before the memory controller 300 issues the data output command. For example, when the ready/busy signal RBn transmitted from the NAND chip CPA has made a transition from the low level to the high level, the I/F chip 210 transmits the data output command. Alternatively, when a time period that has passed after the read command has been transmitted to the NAND chip CPA exceeds a maximum allowable time period of the read operation of the NAND chip CPA, the I/F chip 210 transmits the data output command.

Upon receiving the data output command, at time t6, the NAND chip CPA starts data output preparation. Time t6 to time t8 is the data output preparation period tWHR2. When the data output preparation period tWHR2 has finished, from time t8 to time t11, the NAND chip CPA transmits read data to the I/F chip 210 via the DQ (CH0) bus.

When the read operation period of the NAND chip CPC has finished at time t6, the I/F chip 210 transmits a data output command to the NAND chip CPC at time t6 before the memory controller 300 issues the data output command.

Upon receiving the data output command, at time t7, the NAND chip CPC starts data output preparation. Time t7 to time t9 is the data output preparation period tWHR2. When the data output preparation period tWHR2 has finished, from time t9 to time t12, the NAND chip CPC transmits read data to the I/F chip 210 via the DQ (CH1) bus.

The memory controller 300 transmits a new read command A for the NAND chip CPA via the DQ bus at time t6, and transmits a new read command C for the NAND chip CPC via the DQ bus at time t7.

As described above, the memory controller 300 can transmit the new read commands A and C for the NAND chips CPA and CPC in parallel with a period during which the NAND chips CPA and CPC are performing data output preparation (time t6 and time t7).

From time t8 to time t11, the I/F chip 210 temporarily holds, in the storage unit 2, data that has been transmitted from the NAND chip CPA to the DQ (CH0) bus. Similarly, from time t9 to time t12, the I/F chip 210 temporarily holds, in the storage unit 2, data that has been transmitted from the NAND chip CPC to the DQ (CH1) bus.

Thereafter, the memory controller 300 transmits a data output command for the NAND chip CPA via the CA bus at time t10 in parallel with a period during which the NAND chip CPA outputs data to the DQ (CH0) bus.

Then, at time t11, the memory controller 300 transmits a select chip enable (SCE) command instructing the start of outputting data of the NAND chip CPA, via the CA bus, in accordance with the specifications of the SCA protocol. During a period from time t12 to time t15, the I/F chip 210 that has received this command transmits, via the DQ bus, data that has been read from the NAND chip CPA and has been held in the storage unit 2. More specifically, at time t14, the memory controller 300 transmits a select chip terminate (SCT) command instructing the termination of outputting data, via the CA bus. At time t15, the I/F chip 210 that has received this command terminates a process of transmitting, via the DQ bus, the data that has been read from the NAND chip CPA and has been held in the storage unit 2.

At time t11 when the data output period on the DQ (CH0) bus finishes, the I/F chip 210 transmits, via the DQ (CH0) bus, the read command A that has been transmitted by the memory controller 300 at time t6. The NAND chip CPA receives the read command A, and performs a read operation to read data that corresponds to the received read command A from the NAND chip CPA, from time t12 to time t15.

At time t12 when the data output period on the DQ (CH1) bus finishes, the I/F chip 210 transmits, via the DQ (CH1) bus, the read command C that has been transmitted by the memory controller 300 at time t7. The NAND chip CPC receives the read command C, and performs an operation to read data that corresponds to the received read command C from the NAND chip CPC, from time t13 to time t16.

At time t15, the memory controller 300 transmits, via the CA bus, an SCE command instructing the start of outputting data of the NAND chip CPC. During a period from time t16 to time t20, the I/F chip 210 that has received this command transmits, via the DQ bus, data that has been read from the NAND chip CPC and has been held in the storage unit 2. More specifically, at time t19, the memory controller 300 transmits, via the CA bus, a command instructing the termination of outputting data. At time t20, the I/F chip 210 that has received this command terminates a process of transmitting, via the DQ bus, the data that has been read from the NAND chip CPC and has been held in the storage unit 2.

At time t15 when the read operation of the NAND chip CPA finishes, the I/F chip 210 transmits a data output command to the NAND chip CPA via the DQ (CH0) bus. From time t15 to time t26, the I/F chip 210 and each of the NAND chips CPA and CPC perform operations that are similar to those from time t5 to t15.

At time t16 and time t17, the memory controller 300 transmits new read commands A and C to the I/F chip 210 via the CA bus in parallel with a period during which the NAND chips CPA and CPC are performing data output preparation. From time t16 to time t27, the memory controller 300 performs operations that are similar to those from time t6 to time t16.

As described above, in the first specific example, before the memory controller 300 issues the data output command, the I/F chip 210 issues the data output command to the NAND chips CPA and CPC, and sequentially holds, in the storage unit 2, pieces of data that have been read from the NAND chips CPA and CPC and have been transmitted via the DQ (CH0) bus and the DQ (CH1) bus. Therefore, when the memory controller 300 subsequently issues the data output commands A and C, the pieces of data that have been held in the storage unit 2 can be quickly transmitted to the memory controller 300. This reduces a period of outputting data to the memory controller 300.

In addition, in a case where the memory controller 300 adopts the SCA protocol, after the storage unit 2 has held the data, the memory controller 300 issues a data output command, and issues an SCE command to start outputting data. Then, the I/F chip 210 transmits the data that has been held by the storage unit 2 to the memory controller 300. After the memory controller 300 has issued an SCT command to terminate data transmission, the I/F chip 210 terminates data transmission.

### A Comparative Example

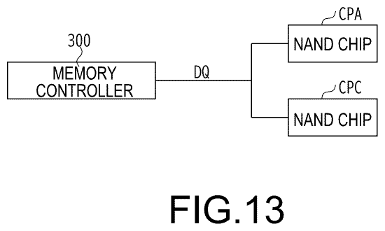

FIG. 13 is a diagram illustrating a connection relationship among a memory controller 300 and two NAND chips CPA and CPC according to a comparative example. The memory controller 300 according to the comparative example accesses the two NAND chips CPA and CPC without using the I/F chip 210. The memory controller 300 and the two NAND chips CP are connected by a DQ bus. The DQ bus transmits a command/address and data.

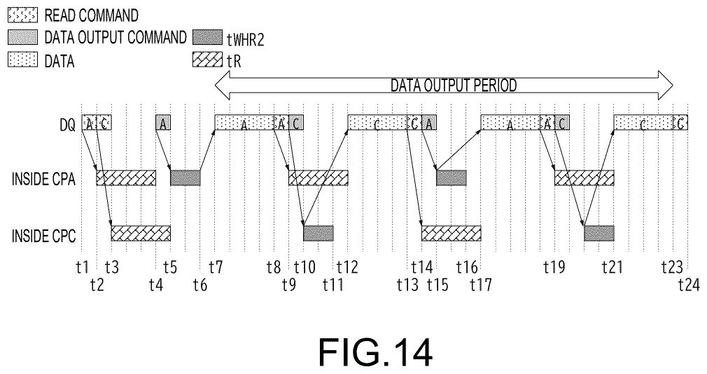

FIG. 14 is a timing diagram of the comparative example. FIG. 14 illustrates timings of the DQ bus, an internal operation of the NAND chip CPA, and an internal operation of the NAND chip CPC.

The memory controller 300 transmits a read command A for the NAND chip CPA via the DQ bus at time t1, and transmits a read command C for the NAND chip CPC via the DQ bus at time t2.

During a period tR from time t2 to time t4, the NAND chip CPA performs a read operation that corresponds to the read command A. During a period tR from time t3 to time t5, the NAND chip CPC performs a read operation that corresponds to the read command C.

When the read operation of the NAND chip CPA has finished, at time t4, the memory controller 300 transmits a data output command for the NAND chip CPA via the DQ bus. The NAND chip CPA performs data output preparation during a period tWHR2 from time t5 to time t6, and transmits data for which data output preparation has been completed via the DQ bus during a period from time t7 to time t8. The memory controller 300 acquires data on the DQ bus during a period from time t7 to time t8, transmits a new read command for the NAND chip CPA via the DQ bus at time t8, and transmits a data output command for the NAND chip CPC via the DQ bus at time t9. The NAND chip CPA performs a read operation during a period tR from time t9 to time t12. The NAND chip CPC performs data output preparation that corresponds to the read command C during a period tWHR2 from time t10 to time t11, and transmits data for which data output preparation has been completed via the DQ bus from time t12 to time t13.

The memory controller 300 acquires data that corresponds to the read command C from time t12 to time t13, transmits a new read command C for the NAND chip CPC via the DQ bus at time t13, and transmits a data output command for the NAND chip CPA via the DQ bus at time t14. The NAND chip CPC performs a read operation during a period tR from time t14 to time t17. The NAND chip CPA performs data output preparation during a period tWHR2 from time t15 to time t16. Thereafter, from time t17 to time t24, operations that are similar to those from time t7 to time t14 are performed.

As described above, in the comparative example, the memory controller 300 fails to issue a new command during data output preparation periods of the NAND chips CPA and CPC, and therefore the latency increases, and the access speed fails to be improved.

### Second Specific Example

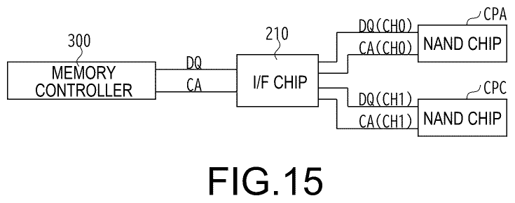

FIG. 15 is a diagram illustrating a connection relationship among the memory controller 300, the I/F chip 210, and the two NAND chips CPA and CPC according to the second specific example. The second specific example is the same as the first specific example in that the memory controller 300 adopts the SCA protocol, but is different from the first specific example in that the I/F chip 210 and each of the NAND chips CP have a CA bus dedicated to a command/address and a DQ bus dedicated to data.

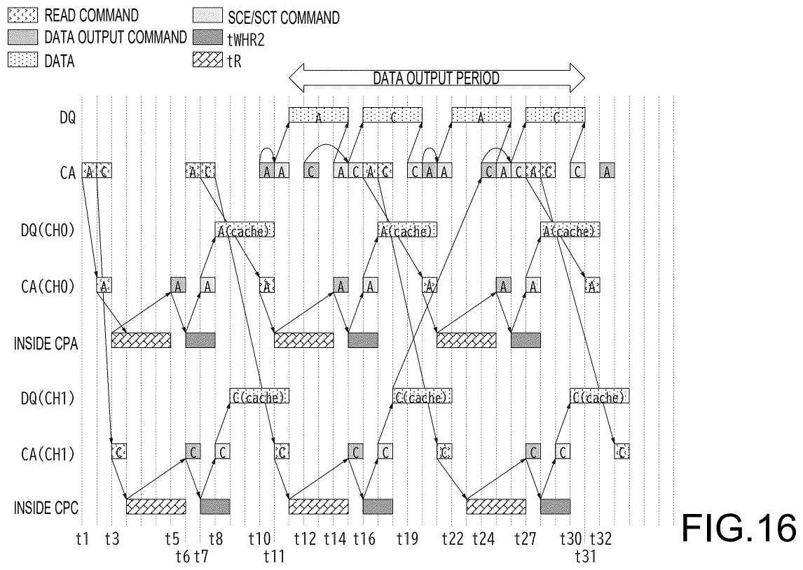

FIG. 16 is a timing diagram of the second specific example. FIG. 16 illustrates timings of a DQ bus and a CA bus between the memory controller 300 and the I/F chip 210, a DQ (CH0) bus and a CA (CH0) bus between the I/F chip 210 and the NAND chip CPA, an internal operation of the NAND chip CPA, a DQ (CH1) bus and a CA (CH1) bus between the I/F chip 210 and the NAND chip CPC, and an internal operation of the NAND chip CPC. Hereinafter, a difference from the timings of the first specific example illustrated in FIG. 12 will be mainly described.

In the second specific example, the DQ (CH0) bus and the CA (CH0) bus are provided between the I/F chip 210 and the NAND chip CPA, and therefore the I/F chip 210 transmits a data output command to the CA (CH0) bus at time t5, and then transmits an SCE command to start data output to the CA (CH0) bus at time t7. Similarly, the I/F chip 210 transmits a data output command to the CA (CH1) bus at time t6, and then transmits an SCE command to start data output to the CA (CH1) bus at time t8.

In addition, at time t10 when the NAND chip CPA is transmitting data that corresponds to the read command A via the DQ (CH0) bus, the I/F chip 210 transmits a new read command A via the CA (CH0) bus. Similarly, at time t11 when the NAND chip CPC is transmitting data that corresponds to the read command C via the DQ (CH1) bus, the I/F chip 210 transmits a new read command C via the CA (CH1) bus.

As a result, a data output period (time t12 to time t31) in the second specific example becomes shorter than a data output period (time t12 to time t31) in the first specific example, and throughput can be improved.

### Third Specific Example

The memory controller 300, the I/F chip 210, and the two NAND chips CPA and CPC according to a third specific example have a connection relationship that is similar to that of the second specific example illustrated in FIG. 15. In the third specific example, the start of data output can be instructed at a timing when data held in the storage unit 2 in the I/F chip 210 is started to be transmitted via the DQ bus, and the termination of data output can be instructed at a timing when the transfer of the data held in the storage unit 2 has been finished, and therefore a command indicating the start of data output and a command indicating the termination of data output are omitted.

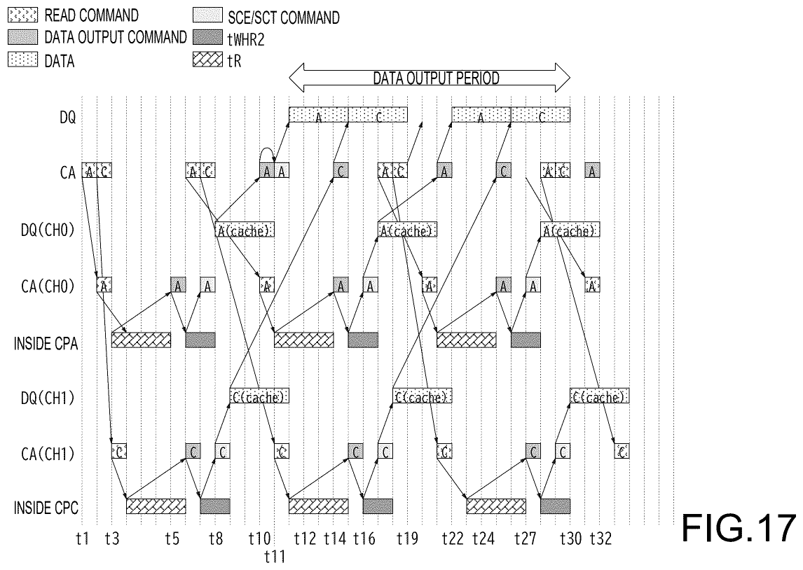

FIG. 17 is a timing diagram of the third specific example. At time t11, similarly to time t11 in FIG. 16, the memory controller 300 transmits a command instructing the start of data output via the CA bus. Thereafter, the memory controller 300 does not transmit a command instructing the termination of data output and a command instructing the start of data output to the CA bus.

As a result, a data output period (time t12 to time t27) in the third specific example can be reduced in comparison with the data output period (time t12 to t31) in the second specific example, and throughput can be improved.

In the I/F chip 210 according to the third specific example, in a case where the memory controller 300 adopts the SCA protocol, after the storage unit 2 has held data, the memory controller 300 issues a data output command, and issues an SCE command to start data output. After the memory controller 300 has issued the SCE command, the I/F chip 210 according to the third specific example transmits all pieces of corresponding data that have been held in the storage unit 2 to the memory controller 300. Thereafter, when the memory controller 300 has issued a data output command, the I/F chip 210 according to the third specific example transmits all pieces of corresponding data that have been held in the storage unit 2 to the memory controller 300, without waiting for an SCE command to start data output.

More specifically, in the I/F chip 210 according to the third specific example, the storage unit 2 holds plural pieces of data that have been output from the plurality of NAND chips CP. Thereafter, after the memory controller 300 has first issued a data output command and has issued an SCE command to start data output, the I/F chip 210 according to the third specific example transmits first data of the plural pieces of data to the memory controller 300. Then, in a case where the memory controller 300 issues a data output command second time and the times that follow, the I/F chip 210 according to the third specific example transmits all pieces of corresponding data that have been held in the storage unit 2 to the memory controller 300, without waiting for the SCE command to start data output from the memory controller 300.

### Fourth Specific Example

In the first to third specific examples, the memory controller 300 adopts the SCA protocol. In contrast, a fourth specific example is different from the first to third specific examples in that the memory controller 300 adopts the normal protocol.

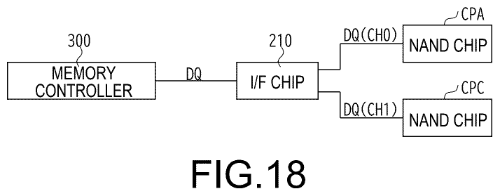

FIG. 18 is a diagram illustrating a connection relationship among the memory controller 300, the I/F chip 210, and the two NAND chips CPA and CPC according to the fourth specific example. The memory controller 300 and the I/F chip 210 transmit a command/address and data via a DQ bus. In addition, the I/F chip 210 and the NAND chip CPA transmit a command/address and data via a DQ (CH0) bus, and the I/F chip 210 and the NAND chip CPC transmit a command/address and data via a DQ (CH1) bus.

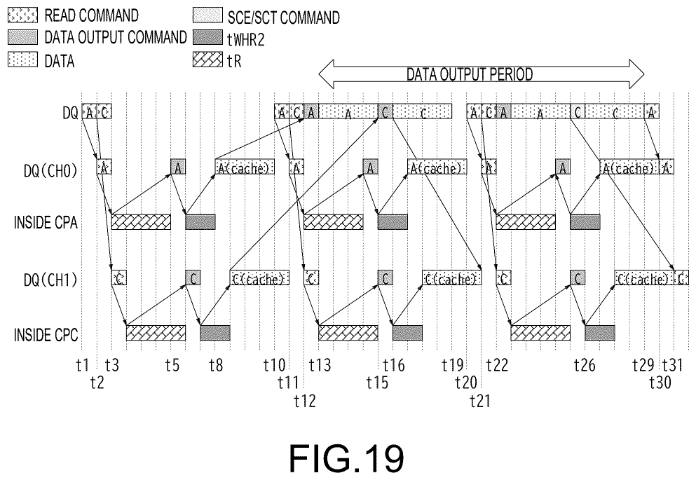

FIG. 19 is a timing diagram of the fourth specific example. FIG. 19 illustrates timings of the DQ bus between the memory controller 300 and the I/F chip 210, the DQ (CH0) bus between the I/F chip 210 and the NAND chip CPA, an internal operation of the NAND chip CPA, the DQ (CH1) bus between the I/F chip 210 and the NAND chip CPC, and an internal operation of the NAND chip CPC. Hereinafter, a difference from the timings of the first specific example illustrated in FIG. 12 will be mainly described.

In the fourth specific example, a command/address and data are transmitted between the memory controller 300 and the I/F chip 210 via the DQ bus. Therefore, at time t10 after the I/F chip 210 has transmitted a data output command A via the DQ (CH0) bus at time t5 and the NAND chip CPA has transmitted corresponding data to the DQ (CH0) bus, the memory controller 300 transmits a new read command A via the DQ bus. Then, at time t11, the memory controller 300 transmits a new read command C via the DQ bus. As described above, a timing at which the memory controller 300 issues the new read commands A and C is considerably later than the timing in FIG. 12.

Thereafter, at time t12, the memory controller 300 transmits the data output command A via the DQ bus. In response to this, from time t13 to time t15, the I/F chip 210 transmits data held in the storage unit 2 via the DQ bus.

At time t15, the memory controller 300 transmits the data output command C via the DQ bus. In response to this, from time t16 to time t19, the I/F chip 210 transmits data held in the storage unit 2 via the DQ bus.

During periods from time t11 to time t21 and from time t21 to time t30, operations that are similar to those during a period from time t2 to time t11 are performed between the I/F chip 210 and the NAND chips CPA and CPC.

In the fourth specific example, the memory controller 300 and the I/F chip 210 transmit a command/address and data via the DQ bus. Therefore, in the fourth specific example, a data output period t13 to t29 is longer than the data output periods in the first to third specific examples. However, in the fourth specific example, before the memory controller 300 issues a data output command, the I/F chip 210 transmits the data output command to the NAND chips CPA and CPC, reads ahead pieces of data stored in the NAND chips CPA and CPC, and holds the read-ahead pieces of data in the storage unit 2. Therefore, in the fourth specific example, similarly to the first to third specific examples, when the memory controller 300 has issued the data output command, data held in the storage unit 2 can be quickly transmitted to the memory controller 300, and throughput can be improved.

### Mounting Form of Semiconductor Memory Device 200

As illustrated in FIG. 9, the semiconductor memory device 200 that includes the I/F chip 210 and the plurality of NAND chips CP according to the present embodiment may be formed as one integrated chip, or may be formed as separate chips. Hereinafter, a representative mounting form of the semiconductor memory device 200 that includes the I/F chip 210 and the plurality of NAND chips CP will be described.

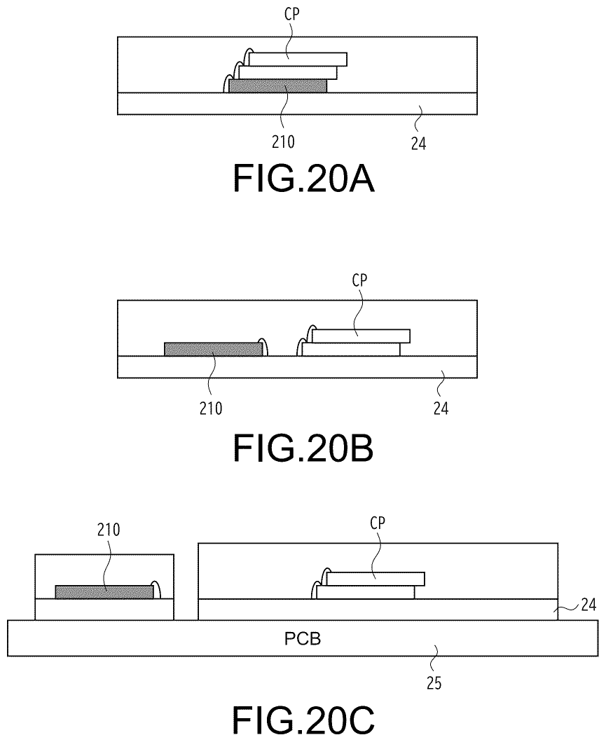

FIG. 20A is a diagram illustrating a first mounting example of the semiconductor memory device 200 according to the present embodiment. The semiconductor memory device 200 according to the first mounting example is an integrated chip in which the I/F chip 210 according to the present embodiment is mounted on a support substrate 24 and the plurality of NAND chips CP is stacked thereon to be packaged. The integrated chip according to the first mounting example can reduce the chip area.

FIG. 20B is a diagram illustrating a second mounting example of the semiconductor memory device 200 according to the present embodiment. The semiconductor memory device 200 according to the second mounting example is an integrated chip in which the I/F chip 210 according to the present embodiment and the plurality of NAND chips CP that has been stacked are disposed on a support substrate 24 to be adjacent to each other, and are packaged. In the integrated chip according to the second mounting example, the chip area is larger than that in the first mounting example, but wiring between the integrated chip and the NAND chips CP is easily performed.

FIG. 20C is a diagram illustrating a third mounting example of the semiconductor memory device 200 according to the present embodiment. In the semiconductor memory device 200 according to the third mounting example, a package member of the I/F chip 210 according to the present embodiment and a package member of the plurality of NAND chips CP that has been stacked are disposed on a print circuit board (PCB) 25 to be adjacent to each other. The integrated chip and the NAND chips CP are separately packaged, and this increases noise resistance.

As described above, the I/F chip 210 according to the present embodiment includes the control unit 1 that is capable of transmitting a command (for example, the data output command) to a memory chip (for example, the NAND chip CP) at a timing independent of a timing of inputting a command (for example, the read command) that has been issued by the memory controller 300, and therefore it is possible to improve the throughput of outputting data to the memory controller 300.

While certain embodiments have been described, these embodiments have been presented by way of example only, and are not intended to limit the scope of the disclosures. Indeed, the novel methods and systems described herein may be embodied in a variety of other forms; furthermore, various omissions, substitutions and changes in the form of the methods and systems described herein may be made without departing from the spirit of the disclosures. The accompanying claims and their equivalents are intended to cover such forms or modifications as would fall within the scope and spirit of the disclosures.

1. An interface chip comprising:
a first signal line, a second signal line, and a third signal line, each of the first signal line, the second signal line, and the third signal line being configured to receive a signal from a memory controller;
a plurality of fourth signal lines, each of the plurality of fourth signal lines being configured to transmit and receive a signal to and from the memory controller;
a plurality of fifth signal lines, each of the plurality of fifth signal lines being configured to transmit and receive a signal to and from a first memory chip including a plurality of memory cells;
a storage; and
a controller configured to, in a case where a first signal transmitted from the memory controller via the third signal line is at a first logic level:
transmit, after receiving a first command for the read operation transmitted from the memory controller via the first signal line and the second signal line, a second command for the read operation, the second command corresponding to the first command, to the first memory chip via a plurality of fifth signal lines;
transmit a fourth command for data output to the first memory chip via the plurality of fifth signal lines, after the read operation performed by the first memory chip and before receiving a third command for the data output from the memory controller via the first signal line and the second signal line;
receive, via the plurality of fifth signal lines, first data being output from the first memory chip in response to the fourth command transmitted to the first memory chip;
cause the storage to hold the received first data; and
transmit the held first data to the memory controller via a plurality of fourth signal lines, after receiving the third command.

2. The interface chip according to claim 1, wherein
the controller is further configured to, in a case where the first signal is at a second logic level being different from the first logic level:
transmit, after receiving a fifth command for the read operation transmitted from the memory controller via the plurality of fourth signal lines, a sixth command for the read operation, the sixth command corresponding to the fifth command, via the plurality of fifth signal lines;
transmit an eighth command for the data output to the first memory chip via the plurality of fifth signal lines, after the read operation performed by the first memory chip and before receiving a seventh command for the data output from the memory controller via the plurality of fourth signal lines;
receive, via the plurality of fifth signal lines, second data being output from the first memory chip in response to the eighth command transmitted to the first memory chip;
hold the received second data; and
transmit the held second data to the memory controller via the plurality of fourth signal lines, after receiving the seventh command.

3. The interface chip according to claim 2, further comprising:
a sixth signal line being configured to receive a signal from the memory controller; and
a plurality of seventh signal lines being configured to transmit and receive a signal to and from a second memory chip including a plurality of memory cells, wherein
the controller is further configured to, in a case where a second signal being transmitted from the memory controller via the sixth signal line is at the first logic level:
transmit a tenth command for the read operation to the second memory chip via the plurality of seventh signal lines, after receiving a ninth command for the read operation, the tenth command corresponding to the ninth command, the ninth command being transmitted from the memory controller via the first signal line and the second signal line;
transmit a twelfth command for the data output to the second memory chip via the plurality of seventh signal lines, after the read operation performed by the second memory chip and before receiving an eleventh command for the data output, the eleventh command been transmitted from the memory controller via the first signal line and the second signal line;
receive, via the plurality of seventh signal lines, third data being output from the second memory chip in response to the twelfth command transmitted to the second memory chip;
hold the received third data; and
transmit the held third data to the memory controller via the plurality of fourth signal lines, after receiving the eleventh command.

4. The interface chip according to claim 3, wherein
the controller is further configured to, in a case where the second signal is at the second logic level:
transmit, after receiving a thirteenth command for the read operation transmitted from the memory controller via the plurality of fourth signal lines, a fourteenth command for the read operation, the fourteenth command corresponding to the thirteenth command, to the second memory chip via the plurality of seventh signal lines;
transmit a sixteenth command for the data output to the second memory chip via the plurality of seventh signal lines, after the read operation performed by the second memory chip and before receiving a fifteenth command for the data output from the memory controller via the plurality of fourth signal lines;
receive, via the plurality of seventh signal lines, fourth data being output from the second memory chip in response to the sixteenth command transmitted to the second memory chip;
hold the received fourth data; and
transmit the held fourth data to the memory controller via the plurality of fourth signal lines, after receiving the fifteenth command.

5. The interface chip according to claim 1, wherein
the first command includes a first address corresponding to a first memory cell to be read from among the plurality of memory cells of the first memory chip, and
a second address included in the second command corresponds to the first memory cell.

6. The interface chip according to claim 5, wherein
the third command includes a third address corresponding to the first memory cell, and
a fourth address included in the fourth command corresponds to the first memory cell.

7. The interface chip according to claim 6, wherein
the first memory chip includes a latch circuit and,
the first memory chip is configured to read data being stored in the first memory cell, in response to the second command, and store the read data in the latch circuit.

8. The interface chip according to claim 7, wherein
the first memory chip is configured to output the first data including the data stored in the latch circuit, in response to the fourth command.

9. The interface chip according to claim 2, wherein
the sixth command is identical to the fifth command, and the eighth command is identical to the seventh command.

10. The interface chip according to claim 2, wherein
the first logic level is a high level, and the second logic level is a low level.

11. The interface chip according to claim 1, further comprising
an eighth signal line being configured to receive a signal from the memory controller, wherein
in a case where the first signal is at the first logic level, the controller is further configured to use, as a timing signal, a third signal being received via the eighth signal line, and specify the first command based on a fourth signal being received via the first signal line and a fifth signal being received via the second signal line.

12. The interface chip according to claim 1, wherein
the controller is further configured to transmit the fourth command to the first memory chip, after a predetermined time period passes after transmitting the second command to the first memory chip.

13. The interface chip according to claim 5, wherein
after the second command is transmitted to the first memory chip, when a logic of a predetermined signal changes, the controller is configured to transmit the fourth command to the first memory chip, the predetermined signal being transmitted from the first memory chip and indicating an operation state.

14. The interface chip according to claim 13, wherein
the predetermined signal is a ready/busy signal.

15. The interface chip according to claim 1, wherein
after receiving the third command, the controller is configured to transmit the held first data, to the memory controller via the plurality of fourth signal lines.

16. The interface chip according to claim 15, wherein
the storage is a static random access memory (SRAM).

17. A semiconductor memory device comprising:
the interface chip according to claim 1; and
the first memory chip.

18. A semiconductor memory device comprising:
the interface chip according to claim 3;
the first memory chip; and
the second memory chip.

19. A memory system comprising:
the semiconductor memory device according to claim 17; and
the memory controller.
